(19) United States
(12) Patent Application Publication
(10) Pub. No.: US 2009/0001389 A1
(43) Pub. Date: Jan. 1, 2009

(54) HYBRID VERTICAL CAVITY OF MULTIPLE WAVELENGTH LEDS

(75) Inventors: DONGXUE WANG, PALATINE, IL (US); KEVIN W. JOHNSON, MUNDELEIN, IL (US)

Correspondence Address: AKERMAN SENTERFITT, P.O. BOX 3188, WEST PALM BEACH, FL, 33402-3188, US

(73) Assignee: MOTOROLA, INC., SCHAUMBURG, IL (US)

(21) Appl. No.: 11/769,977

(22) Filed: Jun. 28, 2007

(51) Int. Cl. H01L 33/00

(52) U.S. Cl. 257/89; 257/88; 257/98; 257/E33.069

(57) ABSTRACT

A solid state device (200) for a hybrid vertical cavity of multiple wavelength LEDs is provided. The solid state device can include a hybrid vertical cavity formed by a cascading of a first sub-cavity (210) and a second sub-cavity (220) to share a mirror (350) within the solid state device. The hybrid vertical cavity can collimate the first accumulated light (213) and the second accumulated light (223) to increase an efficiency of total emitted light. In one arrangement, the total emitted light can be directed to a phosphor to generate a white light.

### FIELD OF THE INVENTION

The present invention relates to solid state lighting and, more particularly, to a hybrid vertical cavity of multiple wavelength Light Emitting Diodes (LEDs).

### BACKGROUND

Solid state lighting devices can provide high brightness and uniform illumination. A solid state lighting device such as a Light Emitting Diode (LED) is a compact element that provides high lighting efficiency. The LED is a semiconductor device that emits light in response to an applied electric current, or field, which constitutes a form of electroluminescence. The color of the emitted light, which depends on the composition and quality of the semi-conducting material used, can be infrared, visible or near-ultraviolet.

In one arrangement, phosphors can be introduced onto the LED to generate light by phosphorescence, which is a sustained glowing after exposure to the applied electric current, or field. A single LED that generates a narrowband light can be coated, or doped, with an active phosphor material to produce wideband light. The phosphors can produce light with colors other than the color of the light produced by the LED. For example, a blue LED that emits a blue light can be coated with a phosphor that absorbs the blue light, and in response, produces red and green light.

It is generally desired for a solid state lighting device used as a flash for a mega-pixel camera phone to produce white light, which is the spectrum of all colors. In practice, white light can be generated from red, green, and blue light. One attempt of the prior art to combine different color LEDs in a single solid state device to produce white light is shown in FIG. 1. The dual LED 100 can include a first LED and a second LED laterally positioned on top of one other.

As shown in FIG. 2, the dual LED 100 can include a blue LED 101 with a corresponding blue phosphor to produce a blue and red light and a green LED with a corresponding green phosphor to produce a green light. However, the blue LED 101 cannot adequately or efficiently generate red light as a result of light absorption by the phosphors. Much of the light generated is partially reflected within the solid state device where it gets absorbed and turns into additional heat thereby lowering the lighting efficiency.

The parallel approach to combining dual LEDS suffers color breakdown at a far field of the device where the light is emitted. As shown in FIG. 3, the blue and green lights are dispersed throughout the interior of the device and interfere with one another thereby disrupting the distribution of light frequencies, and uniformity of colors, emitted. The dispersion reduces the quality and efficiency of light that can be produced by the dual LED 100. Consequently, the dual LED 100 configuration only allows for the production of ultraviolet (UV)/blue light or green light, but not both. Thus, the dual LED 100 configuration cannot emit a combination of lights from two LEDS that properly form to generate white light.

### SUMMARY

One embodiment of the present disclosure is a solid state device that can include a hybrid vertical micro-cavity formed by a cascading of two sub-cavities to share a mirror within the solid state device, wherein the hybrid vertical cavity collimates the first accumulated light and the second accumulated light to increase an efficiency of total emitted light. In one arrangement, the total emitted light can be directed to a phosphor coated on the solid state device to generate a white light. The hybrid vertical cavity can include a first vertical cavity formed between a first filter and the mirror with a first LED between the first filter and the mirror, and the first LED emits a first light with a peak wavelength λ₁ that is reflected by the first filter back within the first cavity, wherein the first filter collimates the second light to produce a first accumulated light, and a second vertical cavity formed between a second filter and the mirror with a second LED between the second filter and the mirror, and the second LED emits a second light with a peak wavelength λ₂ that is reflected by the second filter back within the second cavity, wherein the second filter collimates the second light to produce a second accumulated light.

In one arrangement, the first filter can be a first Distributed Bragg Grating (DBG) reflector that reflects an optical spectrum with a peak wavelength λ₁ of the first light back within the first cavity, and the second filter can be a second Distributed Bragg Grating (DBG) reflector that reflects an optical spectrum with a peak wavelength λ₂ of the second light back within the second cavity. The DBR can be fabricated using AlGaN/GaN layers which are p-doped to improve conductivity. The first LED can emit a green light, and the second LED can emit a blue light, wherein a length of the first cavity is longer than a length of the second cavity to accommodate a longer wavelength of the green light. The size, dimension, and position of a LED can vary in accordance with a wavelength of light emitted by the LED. The hybrid vertical can mix the green (and blue), or blue (and UV), respectively, to produce mixed light that is used to pump special designed phosphors coated on the solid state device to collectively produce a white light. The white light can be used for display backlighting, keyboard lighting, camera flash. projector lighting, bio-application, DNA or molecule identification, or optical data storage on a CD or DVD.

Another embodiment of the present disclosure is a solid state device to form a hybrid vertical cavity of multiple wavelength LEDS. The solid state device can include a substrate that is transparent to light, a first filter layered on the first LED to reflect a first light within a first vertical cavity, accumulate the first light within the first cavity, and emit the first light through the substrate, a first LED layered on the substrate to emit the first light, a second filter layered on the first LED to reflect a second light within a second vertical cavity, accumulate the second light within the second cavity, and emit the second light outside of the second vertical cavity through the first LED, the first filter, and the substrate, a second LED layered on the second filter to emit the second light; and a mirror layered on the second LED to reflect the first light within the first cavity and to reflect the second light within the second cavity. The first LED or the second LED can comprise a n-GaN layer, an active region consist of InGaN/GaN multiple quantum well (MQW) layered on the n-GaN layer, and a p-Gan layered on the active region. In other arrangements, at least one more LED and at least one more filter can be inserted to create at least one more vertical cavity within the solid state device.

The hybrid vertical cavity can serve as a light collimator to increase a light pumping efficiency within a LED. The first filter or the second filter can be Distributed Bragg Grating (DBG) reflectors having a reflectivity index corresponding to a light wavelength of the corresponding first LED or second LED, respectively. The hybrid vertical cavity can be formed by cascading the first vertical cavity with the second vertical cavity to share the mirror. In one arrangement, the first filter can be switched with the mirror to create a top emitting LED device instead of a bottom emitting LED device. In another configuration, a total light can be emitted through the substrate by flip-chip packaging to provide a substrate emitting device.

Yet another embodiment of the present disclosure is a solid state device to emit dual wavelength light within a hybrid vertical cavity. The solid state device can include a first LED that emits a first light with a peak wavelength λ₁ within a first vertical cavity which is reflected within the first vertical cavity and accumulated by a first filter that produces a first accumulated light, wherein the first vertical cavity is formed between a first filter and a mirror, and the first light passes through a second filter and a second LED inside the first vertical cavity, and a second LED that emits a second light with a peak wavelength λ₂ within a second vertical cavity which is reflected within the second vertical cavity and accumulated by a second filter that produces a second accumulated light, wherein the second vertical cavity is formed between the second filter and the mirror, and the second accumulated light passes through the first LED and the first filter outside of the second vertical cavity. The first filter and the second filter can be composed of aluminum gallium nitride (AlGaN) and GaN and monolithically integrated with the first LED and the second LED to share the mirror. As one example, the first filter can reflect green light, and the second filter can reflects ultraviolet or blue light, yet transmit green light. The first LED can include a first active region consist of InGaN/GaN multiple quantum well to emit a green light in the first vertical cavity, and the second LED can include a second active region consist of InGaN/GaN multiple quantum well to emit a blue light in the second vertical cavity. The first vertical cavity can be longer than the second vertical cavity to accommodate a longer wavelength of the green light. The mirror can be a metal material or a dielectric material.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

A “solid state device” can be defined as a packed component comprising at least one semiconductor material. A “cavity” can be defined as a portion of a solid state device to collimate light. The term “collimate” can be defined as aligning a direction of light, for example, within a cavity of a solid state device. A “vertical cavity” can be defined as a vertically oriented cavity in a portion of the solid state device. The term “hybrid cavity” can be defined as at least one cavity within at least one second cavity. A “LED” can be a device that can emit light when electrically biased. The term “emitting” can be defined as generating photons by applying an electric field, or current, to the LED. A “phosphor” can be a substance that exhibits the phenomenon of phosphorescence. The term “pumping” can be defined as impinging a narrowband light, such as that produced by a LED, onto a substance, such as a phosphor, to cause the substance to produce a wideband light. The term “narrowband light” can be defined as light of a wavelength within a predefined color region, such as blue, red, green, or yellow. The term “wideband light” can be defined as light composed of multiple wavelengths of light, such as the combination of red, blue and green light.

The terms “program,” “software application,” “resizing program” and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Further note, the term “exemplary” is used herein to mean “serving as an example, instance, or illustration.” Any embodiment or design described herein as “exemplary” is not necessarily to be construed as preferred or advantageous over other embodiments or designs.

Other embodiments, when configured in accordance with the inventive arrangements disclosed herein, can include a system for performing and a machine readable storage for causing a machine to perform the various processes and methods disclosed herein.

### BRIEF DESCRIPTION OF THE DRAWINGS

The features of the system, which are believed to be novel, are set forth with particularity in the appended claims. The embodiments herein, can be understood by reference to the following description, taken in conjunction with the accompanying drawings, in the several figures of which like reference numerals identify like elements, and in which:

FIG. 1 depicts a dual LED;

FIG. 2 depicts a solid state device configuration corresponding to the dual LED of FIG. 1;

FIG. 3 depicts light dispersion of the dual LED of FIG. 1;

FIG. 4 depicts a hybrid vertical cavity of multiple wavelength LEDs in accordance with an embodiment of the present invention;

FIG. 5 depicts a solid state device for the hybrid vertical cavity of FIG. 4 in accordance with an embodiment of the present invention;

FIG. 6 depicts a first method for collimating light in a hybrid vertical cavity in accordance with an embodiment of the present invention;

FIG. 7 depicts a second method for collimating light in a hybrid vertical cavity in accordance with an embodiment of the present invention;

FIG. 8 depicts layers of the solid state device of FIG. 5 in accordance with an embodiment of the present invention;

FIG. 9 depicts layers a green reflectivity plot for a first filter in accordance with an embodiment of the present invention;

FIG. 10 depicts layers a blue reflectivity plot for a second filter in accordance with an embodiment of the present invention;

FIG. 11 depicts a secondary configuration of the hybrid vertical cavity of FIG. 1 in accordance with an embodiment of the present invention; and

FIG. 12 depicts an exemplary application of the dual LED of FIG. 1 to direct mixed light onto a phosphor to produce a white light.

### DETAILED DESCRIPTION

While the specification concludes with claims defining the features of embodiments of the invention that are regarded as novel, it is believed that the invention will be better understood from a consideration of the following description in conjunction with the figures, in which like reference numerals are carried forward. Embodiments herein can be implemented in a wide variety of ways using a variety of technologies that enable not only the manufacture of hybrid vertical cavity multiple wavelength LED, but the means of combining light from multiple LEDs.

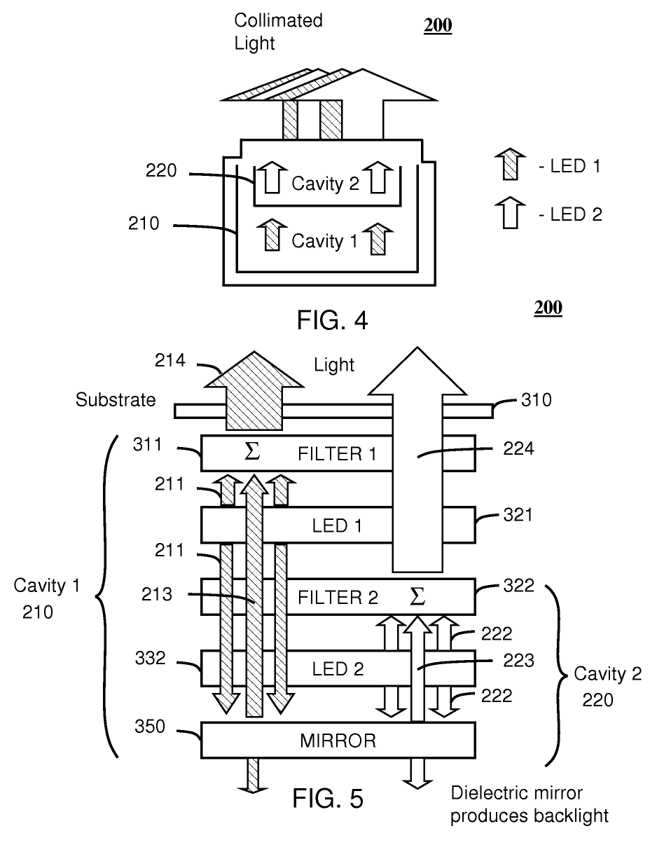

Referring to FIG. 4, a solid state device 200 for emitting multiple wavelength light is shown. The solid state device 200 includes a hybrid vertical cavity containing two LEDs. It should be noted that the solid state device can contain multiple LEDs, each having a corresponding vertical cavity. As illustrated, the solid state device 200 includes a first vertical cavity 210 and a second vertical cavity 220 for collimating light. The first vertical cavity 210 is associated with a first LED collimates light produced by the first LED. The hybridized arrangement of the dual cavity configuration shown in FIG. 4 shows the second cavity 220 within the first cavity 210. The first cavity 210 can span the entire horizontal and vertical aspects of the solid state device 200. The second cavity 220 is associated with a second LED and collimates light produced by the second LED. The second cavity 220 can span the entire horizontal aspect of the solid state device 200 and a smaller portion of the vertical aspect. For example, a vertical height of the first cavity 210 is generally larger than the vertical height of the second cavity 220.

Referring to FIG. 5, a more detailed representation of the components of the solid state device 200 is shown. The solid state device 200 can include a substrate 310, a first filter 311, a first LED 321, a second filter 322, a second LED 332, and a mirror 350. It should be noted that more than the number of LEDs and filters can be included in the solid state device 200 than those shown. The first LED 311 emits a first light 211 (i.e. light from the first LED) in multiple directions within the solid state device 200. Similarly, the second LED 322 emits a second light 222 (i.e. light from the second LED) in multiple directions within the solid state device 200. The first light and the second light can travel freely within the solid state device 200 and are not limited to the left and right column arrangements shown, which are presented for purposes of illustration.

Briefly, the mirror 350 reflects the first light 211 to produce a first reflected light 213 which travels back through the first cavity 210 to the first filter 312. The first filter 311 collimates the light from the first LED 322 within the first cavity 210 by accumulating the first light 211 and the reflected first light 213. Similarly, the mirror 350 reflects the second light 222 to produce a second reflected light 223 which travels back through the second cavity 220 to the second filter 322. The second filter 322 collimates the light from the second LED 332 within the second cavity 220 by accumulating the second light 222 and the reflected second light 223. The first filter 311 is transparent to the second light thus allowing the second light to pass through un-accumulated. The second filter 332 is transparent to the first light thus allowing the first light to pass through un-accumulated. The substrate 310 is transparent to light emitted by the first LED 322 and the second LED 341, and the light reflected off the mirror 350. The light emitted from the solid state device 200 is collimated as a result of the filtering process, which aligns the direction of light and suppresses internal reflection to increase a lighting efficiency.

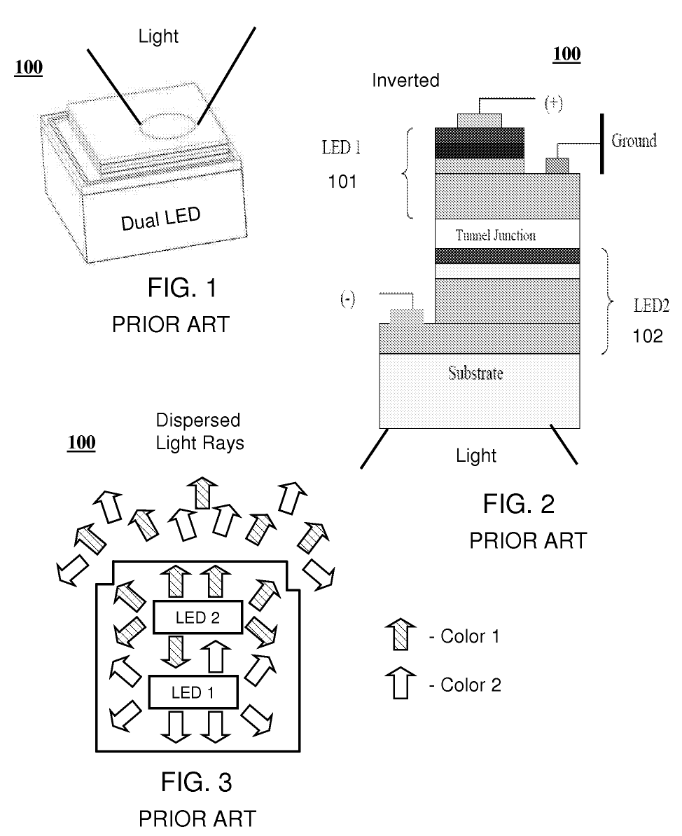

It should be noted that the first light 211 and second light 222 can fill both the first cavity 210 and the second cavity 220. The first cavity 210 and the second cavity 220 establish how light is collimated within the solid state device 200. More specifically, the first cavity 210 channels light between the first filter 311 and the mirror 350, and the second cavity 220 channels light between the second filter 332 and the mirror 350. The respective LEDs are positioned between the filters and the mirror to collimate the light. This allows the filters to accumulate light associated with the respective LED. For example, as shown in FIG. 1, the first LED 321 is positioned between the first filter 311 and the mirror 350 to produce the first cavity 210, and the second LED 332 is positioned between the second filter 322 and the mirror 350 to produce the second cavity 220.

The vertical aspects of the cavities and the positions of the LEDs can also be adjusted based on the wavelength of light emitted. For instance, the first cavity 210 can be lengthened longer than the length of the second cavity 220 to accommodate light of a longer wavelength. As an example, the first cavity can 210 collimate a green light, and the second cavity 220 can collimate blue light, since green light has a longer wavelength than blue light. As shown, the first filter 311 and the mirror 350 form the first vertical cavity 210 for collimating green light, and the second filter 322 and the mirror 350 from the second vertical cavity 220 for collimating blue light. In such a configuration, light traveling within the first cavity travels a longer distance within the solid state device 200 than the smaller path of travel of the second cavity 220.

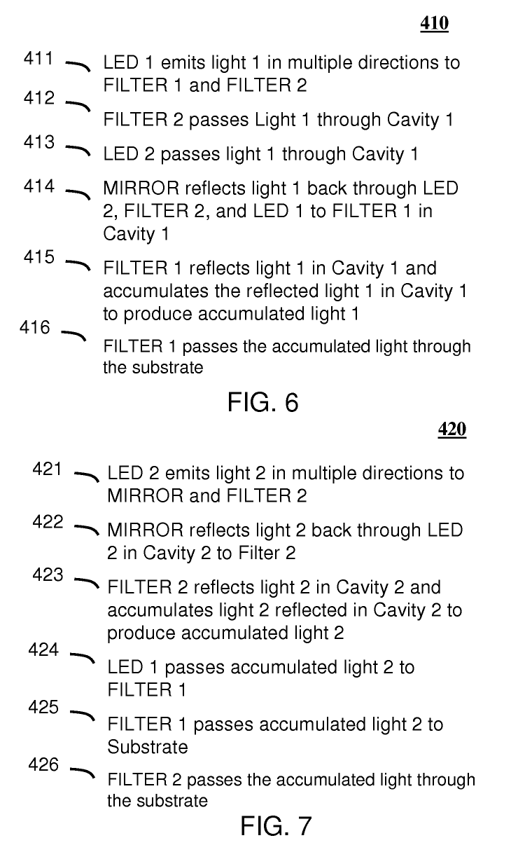

Referring to FIG. 6, an exemplary method 410 for collimating light in the first vertical cavity 210 in accordance with an embodiment of the present invention is shown. The method 410 can include more or less than the number of steps shown. The method 410 does not address the collimation of light in the second cavity 220, which is discussed ahead in FIG. 7. The collimation of light in the first cavity 210 and the collimation of light in the second cavity 220 are presented independently of one another for purposes of discussion, though the total light emitted by the hybrid vertical cavity is a function of lighting in both the first cavity 210 and second cavity 220.

The method 410 can start at state 411, in which the first LED 321 emits the first light 211 in multiple directions, which can include an upward direction towards the first filter 311 and a downward direction towards the second filter 322. As shown in FIG. 5, the light is shown to travel up and down, though it can travel in any direction within the solid state device 200. In the downward direction, as shown in step 412, the second filter 322 passes the first light 211 through the first vertical cavity 210, which then passes through the second LED 332 as shown in step 413. Notably, the first light 211 can pass unobstructed through both the second filter 322 and the second LED 332, which itself generates a second light 222.

At step 414, the mirror 350 reflects the first light 211 to produce a first reflected light 213, which travels back through the second LED 332, the second filter 322, and the first LED 321 to the first filter 311 through the first vertical cavity 210. The mirror 350 can also reflect non-direct light such as that generated from refraction within the solid state device 200.

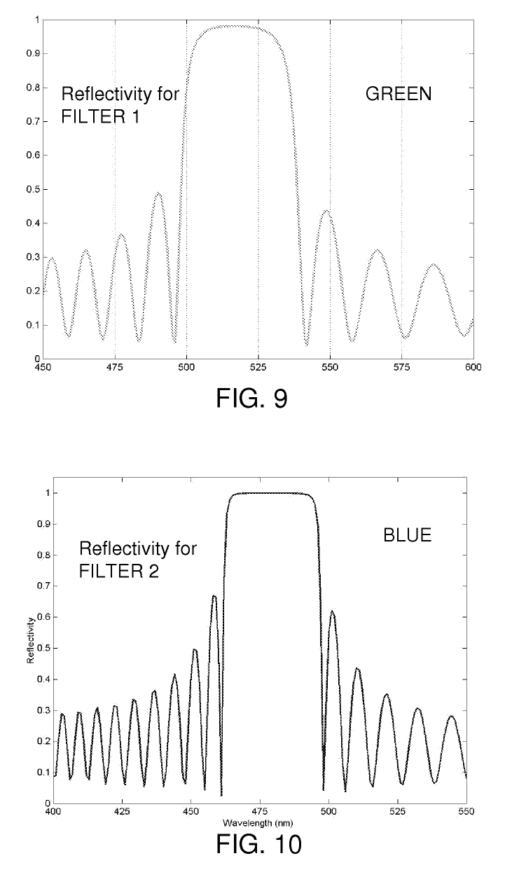

At step 415, the first filter 311 reflects a portion of both the first light 211 and first reflected light 213 back within the first cavity 210. In this case, a first portion of the light is directed out towards the substrate 310, and a second portion of the light is kept within the first cavity 210. The first filter 311 has a reflectivity corresponding to a wavelength of the first light 211 emitted by the first LED 311. More specifically, the first filter is a first Distributed Bragg Grating (DBG) reflector that reflects an optical spectrum with a peak wavelength λ₁ of the first light back within the first cavity. FIG. 9 shows a reflectivity plot for the first filter 221. Notably, the reflectivity is highest for light with a wavelength 505-530 nm in the green spectrum corresponding to the green light emitted by the first LED 321. The reflection of the light within the first cavity 210 aligns the light which is collimated by the first filter 311. The first filter 311 accumulates the reflected lights to produce a first accumulated light 214 which is emitted through the substrate at step 416. The first Distributed Bragg Grating (DBG) reflector can have a layer thicknesses for AlGaN/GaN reflectivity index corresponding to a peak wavelength of the corresponding first LED. As an example, the layer thickness can be ¼ of the wavelength λ₁ divided by a refractive index of AlGaN/GaN.

Referring to FIG. 7, an exemplary method 420 for collimating light in the second vertical cavity 220 in accordance with an embodiment of the present invention is shown. The method 420 can include more or less than the number of steps shown. Briefly, the method 420 does not address the collimation of light in the first cavity 210, which was previously discussed in FIG. 6. The method can start in state 421 in which the second LED 332 emits the second light 222 in multiple directions, which can include an upward direction towards the first LED 321 and a downward direction towards the mirror 350. As shown in FIG. 5, the light is shown to travel up and down, though it can travel in any direction within the solid state device 200. In the downward direction, as shown in step 422.

The mirror 350 reflects the second light 222 back through the second LED 322 in vertical cavity 220 to produce second reflected light 224. The mirror 350 can also reflect non-direct light such as that generated from refraction within the solid state device 200. Both the second light 222 directly emitted by the second LED 332 and the second reflected light 223 travel upward towards the second filter 322. At step 423, the second filter 322 can reflect a portion of both the second light 222 and the second reflected light 223 back within vertical cavity 220. The second filter 322 has a reflectivity corresponding to a wavelength of the second light 222 emitted by the second LED 332. More specifically, the second filter is a second Distributed Bragg Grating (DBG) reflector that reflects an optical spectrum with a peak wavelength λ₂ of the second light back within the second cavity. FIG. 10 shows a reflectivity plot for the second filter 322. Notably, the reflectivity is highest for light with a wavelength 450-470 nm in the blue spectrum corresponding to the blue light emitted by the second LED 332. The second Distributed Bragg Grating (DBG) reflector can have a layer thicknesses for AlGaN/GaN reflectivity index corresponding to a peak wavelength of the corresponding first LED. As an example, the layer thickness can be ¼ of the wavelength λ₂ divided by a refractive index of AlGaN/GaN.

In this step, the second filter 322 also accumulates the light reflected within the vertical cavity 220 to produce second accumulated light 224. Notably, the first LED 321 can pass the second accumulated light 224 unobstructed through both the first LED 321 at step 424, and the first filter 311 at step 425. At step 426, the second filter 332 emits the second accumulated light 224 through the substrate 310, which is transparent to the emitted light.

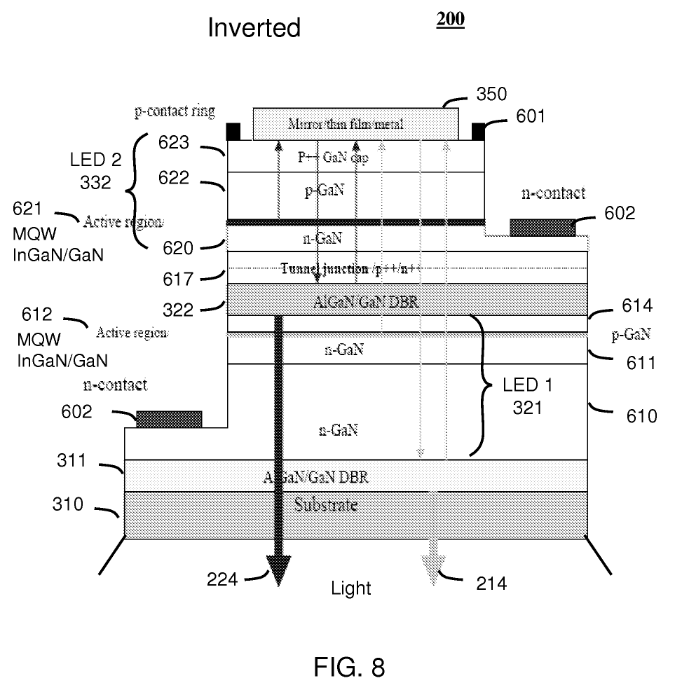

Referring to FIG. 8, an exemplary representation of the solid state device of FIG. 5 is shown. In particular, multiple semiconductor layers of the solid state device 200 are shown in an arrangement that provides a hybrid vertical cavity of dual wavelength LEDs. The solid state device 200 is shown inverted; that is, the light is emitted from the bottom instead of the top for purposes of illustration, though the configuration of the components is unchanged. Various types of semiconductor materials can be used, and the solid state device 200 is not limited to those shown in FIG. 8. The solid state device 200 can include more layers than those show, and is not limited to the size or dimension of the layers or the types of semiconductor material used in the illustration of FIG. 8. The layers can be grown on top of one another during the fabrication of the solid state device (e.g. deposition layers).

The solid state device 200 includes the mirror 350 (shown at top) positioned above the second LED 332, that is positioned above the first filter 322, that is positioned above the first LED 321, that is positioned above the first filter 311, that is positioned above the substrate 310.

The first filter 311 is a Distributed Bragg Grating (DBG) reflector that has reflectivity index corresponding to the first LED 321. The first filter 311 can include a composition of aluminium gallium nitride (AlGaN) and GaN. The first LED 321 includes a n-GaN layer 610, a second n-GaN layer 611, a first active region 612 consisting of InGaN/GaN multiple quantum well (MQW) layered on the n-GaN layer 611, and a p-GaN layer 614. The first active region 612 emits green light in response to an electric voltage applied across n-GaN layer 610 and p-GaN layer 614.

The second filter 322 is a Distributed Bragg Grating (DBG) reflector that has reflectivity index corresponding to the second LED 332. The second filter 311 can also include a composition of AlGaN/GaN though is not limited to this composition. The second LED 33 includes a n-GaN layer 620, a second active region 621 consisting of InGaN/GaN multiple quantum well (MQW) layered on the n-GaN layer 620, a p-GaN layer 622, and a second p-GaN layer 623. The second active region 621 emits blue light in response to an electric voltage applied across n-GaN layer 620 and p-GaN layer 623.

The solid state device 200 includes a p-contact terminal 601 (i.e. positive) and a n-contact (i.e. negative) terminal 602. The p-contact terminal 601 can comprise a separate Ni/Au ring contact, and can be incorporated into the mirror 350. The mirror can be a metal, such as silver, or a dielectric material, such as SiO₂/Ti O₂. In the case of a dielectric material the light generated within the vertical hybrid micro-cavity can also exit from the top in addition to the direction of the substrate 310. The n-contact terminal 602 can be a Ti/Al depositing after partial etching of the n-GaN layers (610 and 620). A power supply can be applied to the p-contact terminal 601 and the negative terminal 602 to source a current of electrons. The electrons can travel through the various layers in an arrangement that produces and collimates light as previously described.

For each LED, the current flows from the p-side, or anode, to the n-side, or cathode, but not in the reverse direction. When an electron meets a hole, it falls into a lower energy level, and releases energy in the form of a photon. When the voltage is applied across n-GaN layer 610 and p-GaN 614 of the first LED 321, UV light is produced that strikes the a first active region 612 and which produces green light of wavelength 505-530 nm. Similarly, when the voltage is applied across n-GaN layer 620 and p-GaN 623 of the second LED 332, UV light is produced that strikes the second active region 621 and which produces blue light of wavelength of 450-470 nm. The tunnel junction 6187 electrically separates the first LED 321 from the second LED 332. It serves as an electron current spreading layer for the first LED 321, and which allows the p-type connection for the first LED 321.

It should be noted that phosphors are not included within the solid state device 200. More specifically, the two active regions serve to produce blue and green light independently which are collimated in the vertical hybrid micro-cavity. Also, the DBG filter are monolithically integrated with the corresponding LEDs to create a hybrid vertical cavity of dual wavelength LEDs. Moreover, the entire cavity of the solid state device 200 includes two cascaded sub-cavities (first cavity 210, and second cavity 220) that share the single mirror 350. The vertical integration of the first LED 321 and the second LED 332 also mitigates a halo effect generally introduce in multi-chip LEDS exhibiting a lateral (e.g. side by side) or stacked (e.g. layer on layer) LED configuration. It should also be noted that the effective area of the DBR is determined by the size of the mirror 350, which can be metal or dielectric. The arrangement of layers can be extended to create additional layers to provide multiple wavelengths. In such regard, the solid state device 200 is a fully integrated package of multiple LEDs that emits multiple wavelengths. As illustrated in FIG. 8, the fully integrated package is a three terminal (one p-contact 601, and two n-contacts 602) that powers a LED pump for each active region to electrically tunnel two colors (e.g. blue and green) in a single device. Moreover, the hybrid vertical cavity of dual LEDs resulting from the layered arrangement efficiently combines and collimates blue and green light, thus providing high color mixing efficiency for red, green, and blue direct light combining. In the hybrid vertical cavity configuration, the solid state device 200 can significantly increase light extraction efficiency by altering spontaneous emission of LEDs (e.g. >20%). The solid state device 100 can also be used in a flip chip configuration by switching the position of the mirror 350 with the first filter 311 as shown in FIG. 7.

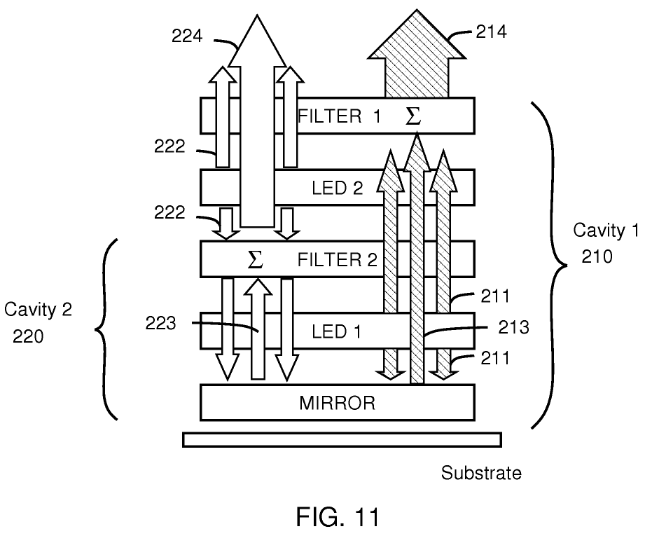

Referring to FIG. 11, another configuration of the solid state device 200 is shown. The solid state device 200 can include a substrate 310, a first filter 311, a first LED 321, a second filter 322, a second LED 332, and a mirror 350. In this configuration, the first filter 311 is switched with the mirror 350 to create a top emitting LED device instead of a bottom emitting LED device.

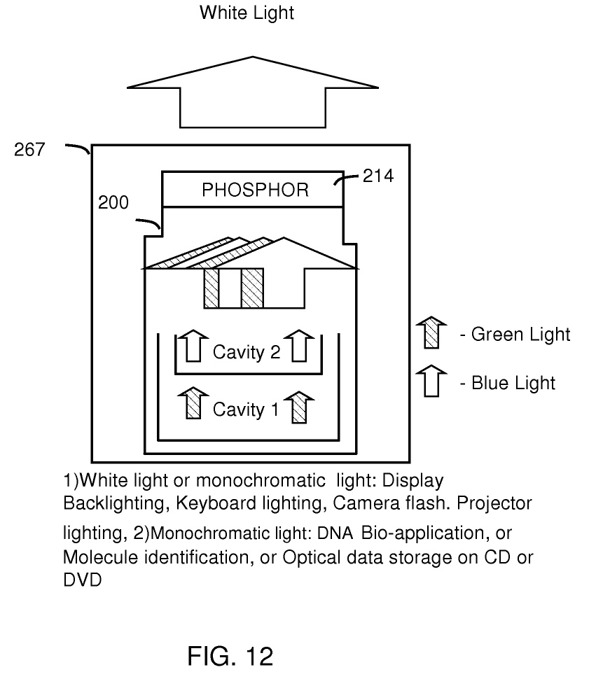

FIG. 12 shows an exemplary application of the solid state lighting device 200. For example, the hybrid vertical cavity of the lighting device 200 can be used to collimate light to increase a light pumping efficiency of a phosphor 214 coated on the solid state device. The hybrid vertical cavity directs the mixed light (e.g. blue and green, or UV and blue) to a phosphor coated on top of the substrate (or mirror). The phosphor emits white light responsive to receiving the mixed light generated by the first LED and the second LED of the solid state device 200. The solid state lighting device 200 can be integrated within a device to produce white light, for example, to provide display backlighting, keyboard lighting, camera flash. projector lighting, bio-application, and DNA or molecule identification. In the case the solid state lighting device is used as a laser diode, the light can be applied to optical data storage, such as CD or DVD

Upon reviewing the aforementioned embodiments, it would be evident to an artisan with ordinary skill in the art that said embodiments can be modified, reduced, or enhanced without departing from the scope and spirit of the claims described below. There are numerous configurations for peer to peer authentication that can be applied to the present disclosure without departing from the scope of the claims defined below. For example, at least one more LED and at least one more filter can be inserted in the sold state device to create at least one more vertical cavity within the solid state device. The solid state device can include additional active regions and filters for various colors besides green and blue. These are but a few examples of modifications that can be applied to the present disclosure without departing from the scope of the claims stated below. Accordingly, the reader is directed to the claims section for a fuller understanding of the breadth and scope of the present disclosure.

While the invention has been described in conjunction with specific embodiments, it is evident that many alternatives, modifications, permutations and variations will become apparent to those of ordinary skill in the art in light of the foregoing description. Accordingly, it is intended that the present invention embrace all such alternatives, modifications, permutations and variations as fall within the scope of the appended claims. While the preferred embodiments of the invention have been illustrated and described, it will be clear that the embodiments of the invention are not so limited. Numerous modifications, changes, variations, substitutions and equivalents will occur to those skilled in the art without departing from the spirit and scope of the present embodiments of the invention as defined by the appended claims.

What is claimed is:

1. A solid state device suitable for use with light emitting diodes or semiconductor laser diodes, comprising
a hybrid vertical micro-cavity formed by a cascading of two sub-cavities to share a mirror within the solid state device,
wherein the hybrid vertical cavity collimates the first accumulated light and the second accumulated light to increase an efficiency of total emitted light.

2. The solid state device of claim 1, wherein the two sub-cavities comprise
a first vertical cavity formed between a first filter and the mirror with a first LED between the first filter and the mirror, and the first LED emits a first light with a peak wavelength λ₁ that is reflected by the first filter back within the first cavity, wherein the first filter collimates the first light to produce a first accumulated light, and
a second vertical cavity formed between a second filter and the mirror with a second LED between the second filter and the mirror, and the second LED emits a second light with a peak wavelength λ₂ that is reflected by the second filter back within the second cavity, wherein the second filter collimates the second light to produce a second accumulated light.

3. The solid state device of claim 2, wherein
the first filter is a first Distributed Bragg Grating (DBG) reflector that reflects an optical spectrum with a peak wavelength λ₁ of the first light back within the first cavity; and the second filter is a second Distributed Bragg Grating (DBG) reflector that reflects an optical spectrum with a peak wavelength λ₂ of the second light back within the second cavity,
wherein the DBR is fabricated using AlGaN/GaN layers, and these layers are p-doped to improve conductivity.

4. The solid state device of claim 2, wherein the first LED emits a green light or blue light, and the second LED emits a blue light or ultraviolet light, respectively, wherein a length of the first cavity is longer than a length of the second cavity to accommodate a longer wavelength of the green or blue light.

5. The solid state device of claim 2, wherein the size, dimension, and position of a LED varies in accordance with a wavelength of light emitted by the LED and optical power of the LED.

6. The solid state device of claim 2, wherein hybrid vertical cavity is used to mix green and blue, or blue and UV, respectively, to produce mixed light, and the mixed light pumps special designed phosphors to collectively produce a white light; and the cavity is also used to mix RGB monochromatic light.

7. The solid state device of claim 6, wherein the white light is used for at least one among display backlighting, keyboard lighting, camera flash. projector lighting, and mixed Green and Blue or Blue and UV can be used in areas of projection, camera flash, bio-application, DNA or molecule identification, and optical data storage on a CD or DVD.

8. The solid state device of claim 6, wherein the first LED emits a green/blue light in the first vertical cavity, and the second LED emits a blue/UV light in the second vertical cavity, the vertical hybrid cavity collimates the blue/UV light and the green/Blue light to produce a mixed light that is directed to a pump phosphor that emits corresponding light responsive to receiving the mixed light. The pumping light from LEDs and light emitted from phosphors collectively form white light. The amount of monochromatic light from each of the dual-wavelength LED can be used to control the color temperature of the white light.

9. A solid state device to form a hybrid vertical cavity of multiple wavelength LEDS, the solid state device comprising:
a substrate that is transparent to light;
a first filter for the first LED to reflect a first light within a first vertical cavity, accumulate the first light within the first cavity, and emit the first light through the substrate;
a first LED coupled to the substrate to emit the first light;
a second filter for the second LED to reflect a second light within a second vertical cavity, accumulate the second light within the second cavity, and emit the second light outside of the second vertical cavity through the first LED, the first filter, and the substrate;
a second LED layered on the second filter to emit the second light; and
a mirror layered on the second LED to reflect the first light within the first cavity and to reflect the second light within the second cavity.

10. The solid state device of claim 9, wherein the first LED or the second LED comprise a n-GaN layer, an active region consisting of InGaN/GaN multiple quantum well (MQW) layered on the n-GaN layer, and a p-GaN layered on the first active region. The amount of Indium in InGaN of MQW determines the peak wavelength of emissions

11. The solid state device of claim 9, further comprising at least one more LED and at least one more filter to create at least one more vertical cavity within the solid state device.

12. The solid state device of claim 9, wherein the hybrid vertical cavity serves as a light collimator to increase a light pumping efficiency of a phosphor coated on the solid state device.

13. The solid state device of claim 9, wherein the first filter or the second filter is Distributed Bragg Grating (DBG) reflectors having layer thicknesses for AlGaN/GaN reflectivity index corresponding to a peak wavelength of the corresponding first LED or second LED, respectively.

14. The solid state device of claim 9, wherein the hybrid vertical cavity is formed by cascading the first vertical cavity with the second vertical cavity to share the mirror.

15. The solid state device of claim 9, wherein the first filter is switched with the mirror to create a top emitting LED device instead of a bottom emitting LED device.

16. The solid state device of claim 9, wherein a major amount of light is emitted through the substrate by flip-chip packaging to provide a substrate emitting device.

17. A solid state device to emit dual wavelength light within a hybrid vertical cavity, comprising
a first LED that emits a first light within a first vertical cavity which is reflected within the first vertical cavity and accumulated by a first filter that produces a first accumulated light, wherein the first vertical cavity is formed between a first filter and a mirror, and the first light passes through a second filter and a second LED inside the first vertical cavity; and
a second LED that emits a second light within a second vertical cavity which is reflected within the second vertical cavity and accumulated by a second filter that produces a second accumulated light, wherein the second vertical cavity is formed between the second filter and the mirror, and the second accumulated light passes through the first LED and the first filter outside of the second vertical cavity.

18. The solid state device of claim 17, wherein first filter and the second filter are composed of aluminium gallium nitride (AlGaN) and GaN and are monolithically integrated with the first LED and the second LED to share the mirror.

19. The solid state device of claim 17, wherein the first filter reflects green (blue) light, and the second filter reflects blue (ultraviolet) light and transmits green (blue) light,
wherein the vertical hybrid cavity collimates the green light (blue) and the blue (UV) light to produce a mixed light, and directs the mixed light to a phosphor that emits white light responsive to receiving the mixed light. The pumping light from LEDs and light emitted from phosphors collectively form white light. The amount of monochromatic light from each of the dual-wavelength LED can be used to control the color temperature of the white light.

20. The solid state device of claim 17, wherein the first LED includes a MQW active region to emit a green (or blue) light in the first vertical cavity, and the second LED includes a second MQW active region to emit a blue (or UV) light in the second vertical cavity, respectively,
wherein the first vertical cavity is longer than the second vertical cavity to accommodate a longer wavelength of the green light.

21. The solid state device of claim 17, wherein the mirror is a metal material or a dielectric material, such that the light can be transmitted through the dielectric material by multiple reflections and transmissions.

22. The solid state device of claim 21, further comprising a phosphor layered on the solid state device to emit corresponding light responsive to receiving the dual wavelength light to mixed light from LEDs to form white light, wherein light emitted by the first LED and the second LED is collected from both a substrate of the solid state device and the mirror and directed to the phosphor.
